(19) United States
(12) Patent Application Publication
(10) Pub. No.: US 2003/0104703 A1
(43) Pub. Date: Jun. 5, 2003

(54) Cleaning composition and method of washing a silicon wafer

(76) Inventors: Jeng-Wei Yang, Chang-Hua City (TW); Tse-Yuan Lo, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/683,247

(22) Filed: Dec. 5, 2001

(51) Int. Cl. H01L 21/302; H01L 21/461

(52) U.S. Cl. 438/706; 438/689

(57) ABSTRACT

The cleaning composition has a first acid for removing copper from the silicon wafer surface, an oxidizing agent for oxidizing the silicon wafer surface to form an oxide thin film and for oxidizing barrier residues on the bevel edges, a second acid for removing the oxide thin film, and deionized (DI) water. The method involves applying the cleaning composition to the silicon wafer surface for a process time, and spin-drying the silicon wafer surface. This removes all residues from the backside surface and the bevel edges of a silicon wafer.

### BACKGROUND OF THE INVENTION

1. Field of the Invention

The invention relates to the washing of a silicon wafer, and more particularly, to a cleaning composition and a method for washing a silicon wafer surface comprising a backside surface and bevel edges.

2. Description of the Prior Art

As the performance of semiconductor devices progress to higher speeds, the use of aluminum as an interconnect material causes a speed bottleneck. Copper has become a preferred alternative material due to its low resistance and low cost. When plating a wafer with copper, e.g., a layer of Tantalum Nitride (TaN) is initially deposited using physical vapor deposition (PVD) to act as a barrier. After the barrier layer has been deposited, a seed copper layer is deposited using sputtering. Bulk copper is then deposited by either PVD or plating.

Nevertheless, as manufacturing integrated circuits use copper interconnects, a problem often occurs in that the copper contaminates the backside and/or the bevel edges of the wafer through the gap between the wafer chuck and the wafer. Moreover, barrier layer materials, such as TaN remain on the bevel edges of the wafer as well. The presence of copper and TaN on the backside and the bevel edges of the wafer cause problems in subsequent fabrication. For instance, some of the contaminants in these areas may flake off, thereby causing particulate problems and cross-contamination during subsequent fabrication.

A conventional solution to the problem is removing the unwanted copper by applying chemicals to the backside of a wafer. An example of the chemicals is a mixture of sulfuric acid (H₂SO₄), hydrogen peroxide (H₂O₂) and deionized (DI) water, with ranges between 1% to 10% H₂SO₄ and 1% to 10% H₂O₂.

However, the mixture merely dissolves copper on the surface of the wafer and is incapable of removing copper, which penetrates into the surface layer of the wafer. Furthermore, the mixture is also incapable of removing copper and TaN on the bevel edges of the wafer, thus causing particulate problems and cross-contamination during subsequent processes.

### SUMMARY OF THE INVENTION

It is therefore a primary objective of the claimed invention to provide a cleaning composition for washing a silicon wafer surface comprising a backside surface and bevel edges to solve the above-mentioned problem.

According to the claimed invention, a cleaning composition comprises a first acid for removing copper from the silicon wafer surface, an oxidizing agent for oxidizing the silicon wafer surface to form an oxide thin film and for oxidizing barrier residues on the bevel edges, a second acid for removing the oxide thin film and the oxidized barrier residue, and deionized (DI) water.

It is an advantage of the claimed invention that the cleaning composition is capable of dissolving copper on the surface of the wafer and removing copper, which penetrates into the surface layer of the wafer. Furthermore, the mixture is also capable of removing copper and TaN on the bevel edges of the wafer to overcome the prior art shortcomings.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a flow chart outlining the process of washing a silicon wafer surface according to the present invention.

### DETAILED DESCRIPTION

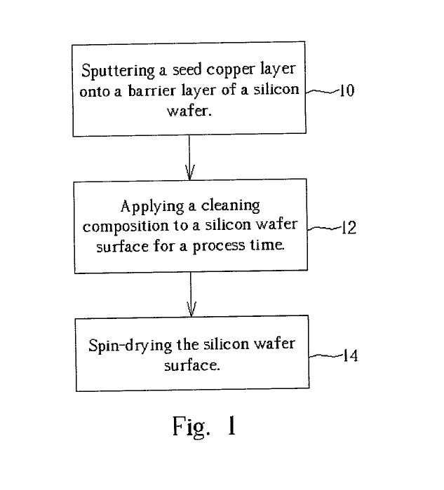

Please refer to FIG. 1. FIG. 1 illustrates a method of washing a silicon wafer surface comprising a backside surface and bevel edges according to the present invention. As shown in FIG. 1, the wafer is delivered to a cleaning apparatus after sputtering of a seed copper layer onto a barrier layer of the wafer (step 10). In a preferred embodiment of the present invention, the cleaning apparatus is the cleaning platform available from Semitool, Inc., or the etching and cleaning system available from SEZ, Inc. Furthermore, the barrier layer comprises either Titanium Nitride (TiN) or Tantalum Nitride (TaN) or any material capable of being used as a barrier.

After sputtering the seed copper layer onto the barrier layer of the silicon wafer, copper and barrier residue may remain on the backside surface and the bevel edges of the wafer. Therefore, the method applies a cleaning composition to the silicon wafer surface for a process time through spraying (step 12) to remove the unwanted contaminants. In a preferred embodiment, the process time is approximately 30 seconds.

According to the present invention, the cleaning composition comprises a first acid for removing copper on the silicon wafer surface, an oxidizing agent for oxidizing the silicon wafer surface to form an oxide thin film and for oxidizing barrier residues on the bevel edges, a second acid for removing the oxide thin film and the oxidized barrier residue, and deionized (DI) water. The first acid is selected from a group consisting of H₂SO₄, HNO₃, CH₃COOH, and H₃PO₄; the oxidizing agent is selected from H₂O₂ or HNO₃; and the second acid is HF. The compositions are as follows: the first acid is present in an amount between 10% to 15% by weight; the oxidizing agent is present in an amount between 30% to 35% by weight; and the second acid is present in an amount between 0.5% to 1.0% by weight.

Once the cleaning composition has been applied to the silicon wafer surface, the method spin-dries the silicon wafer surface (step 14 of FIG. 1). In a preferred embodiment, the application of cleaning composition and spin-drying processes of the silicon wafer surface are performed in the same cleaning apparatus.

As described in the prior art, the mixture of sulfuric aid, hydrogen peroxide and DI water can merely dissolve copper on the surface of the wafer. It is incapable of removing copper, which penetrates into the surface layer of the wafer. The mixture is also incapable of removing copper and barrier residue on the bevel edges of the wafer, thus causing particulate problems and cross-contamination during subsequent fabrication.

In contrast to the prior art, the cleaning composition according to the present invention provides HF for removing the silicon oxide thin film and the oxidized barrier residue formed by the oxidizing agent, such as H₂O₂. Thus the copper, which penetrates into the surface layer of the wafer, and the barrier residues on the bevel edges can be eliminated completely. The experimental results of Total X-Ray Reflectance Fluorescence (TXRF) according to a preferred embodiment are listed below.

[t1]

Test Wafer: 1.5K Cu/Si

| | Process | Cu Quantity (×E10) | | | |
|---|---|---|---|---|---|
| Cleaning | time | Position | Position | Position | |
| composition | (sec) | 1 | 2 | 3 | Result |
| H₂SO₄/ | 10 | 13041.21 | 14348.19 | 14322.49 | Fail |
| H₂O₂/DI | 30 | 13063.24 | 13377.96 | 13796.53 | Fail |
| | 60 | 13556.48 | 13917.64 | 13343.70 | Fail |
| HF/H₂S_{O}₄/ | 10 | 4287.41 | 4995.22 | 5943.09 | Fail |
| H₂O₂/DI | 30 | 1.05 | 1.54 | 2.40 | O.K. |
| | 60 | 1.29 | 1.26 | 0.76 | O.K. |

The experimental results in the table above are acquired from utilizing the cleaning composition of HF, H₂SO₄, H₂O₂ and DI according to a preferred embodiment of the present invention. They are superior to the results acquired from utilizing the cleaning composition without HF according to the prior art. When using the cleaning composition of the present invention for 30 seconds, the unwanted copper is reduced to an acceptable quantity. Therefore, the cleaning composition according to the present invention is capable of removing a substantial amount of contaminants. This reduces costs and improves yield.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A cleaning composition for washing a silicon wafer surface comprising a backside surface and bevel edges, the cleaning composition comprising:
a first acid for removing copper from the silicon wafer surface;
an oxidizing agent for oxidizing the silicon wafer surface to form an oxide thin film and for oxidizing barrier residue on the bevel edges;
a second acid for removing the oxide thin film and the oxidized barrier residue; and
deionized (DI) water.

2. The cleaning composition of claim 1 wherein the first acid is selected from a group consisting of H₂SO₄, HNO₃, CH₃COOH, and H₃PO₄.

3. The cleaning composition of claim 1 wherein the oxidizing agent is selected from H₂O₂ or HNO₃.

4. The cleaning composition of claim 1 wherein the second acid is HF.

5. The cleaning composition of claim 1 wherein the first acid is present in an amount between 10% to 15% by weight; the oxidizing agent is present in an amount between 30% to 35% by weight; and the second acid is present in an amount between 0.5% to 1.0% by weight.

6. The cleaning composition of claim 1 wherein the barrier residue comprises of either TiN or TaN.

7. A method of washing a silicon wafer surface comprising a backside surface and bevel edges, the method comprising:
applying a cleaning composition to the silicon wafer surface for a process time, the cleaning composition comprising:
a first acid for removing copper from the silicon wafer surface;
an oxidizing agent for oxidizing the silicon wafer surface to form an oxide thin film and for oxidizing barrier residue on the bevel edges;
a second acid for removing the oxide thin film and the oxidized barrier residue; and
deionized (DI) water; and
spin-drying the silicon wafer surface.

8. The method of claim 7 wherein the first acid is selected from a group consisting of H₂SO₄, HNO₃, CH₃COOH, and H₃PO₄.

9. The method of claim 7 wherein the oxidizing agent is selected from H₂O₂ or HNO₃.

10. The method of claim 7 wherein the second acid is HF.

11. The method of claim 7 wherein the first acid is present in an amount between 10% to 15% by weight; the oxidizing agent is present in an amount between 30% to 35% by weight; and the second acid is present in an amount between 0.5% to 1.0% by weight.

12. The method of claim 7 wherein the barrier residue comprises either TiN or TaN.

13. The method of claim 7 wherein the process time is approximately 30 seconds.
